(19) United States
(12) Patent Application Publication
(10) Pub. No.: US 2011/0255727 A1
(43) Pub. Date: Oct. 20, 2011

(54) ELECTRONIC APPARATUS

(75) Inventor: Satoshi AZUCHI, Ome-shi (JP)

(73) Assignee: KABUSHIKI KAISHA TOSHIBA, Tokyo (JP)

(21) Appl. No.: 13/090,791

(22) Filed: Apr. 20, 2011

(30) Foreign Application Priority Data
Apr. 20, 2010 (JP) 2010-097331

(51) Int. Cl. H04R 1/02; H05K 7/00; G06F 1/16

(52) U.S. Cl. 381/333; 361/679.27; 361/679.55

(57) ABSTRACT

According to one embodiment, an electronic apparatus includes a housing and a display unit. The housing includes a first end portion, a second end portion and a hinge portion. The display unit is connected to the housing via the hinge portion. The housing further includes a lower cover, an upper cover, a recessed surface and a plurality of projecting portions. The lower cover includes a bottom surface facing a placement surface on which the housing is placed, and an inclined surface provided from the bottom surface over to the first end portion and separating further from the placement surface towards the first end portion. The upper cover covers the lower cover. The recessed surface is recessed from the inclined surface, and includes a hole and a plurality of recessing portions arranged in a lattice manner together with the hole. The projecting portions project from the recessed surface.

### CROSS-REFERENCE TO RELATED APPLICATIONS

This application is based upon and claims the benefit of priority from Japanese Patent Application No. 2010-097331, filed Apr. 20, 2010; the entire contents of which are incorporated herein by reference.

### FIELD

Embodiments described herein relate generally to an electronic apparatus.

### BACKGROUND

Electronic apparatuses such as portable computers are carried by the user. Sometimes such electronic apparatuses are carried in a bag, or other times, they are carried directly in a hand by the users. Not only in the carrying, but also electronic apparatuses are grabbed and held by hand in various situations, for example, when they are put in bags.

Some of the portable electronic apparatuses include a structure to prevent the device from slipping out of the hand. For example, in some cases, a member having a large friction such as rubber is provided at the portion to be grabbed by the user, or a handle to be grabbed by the user is provided.

In the meantime, some of the electronic apparatuses such as portable computers contain a loudspeaker inside the housings. For the loudspeaker, pores are formed in the housing at the location corresponding to the speaker. Some of the electronic apparatuses are devised in terms of design. In these apparatuses, the pores made in the housing may degrade the design of the apparatuses.

### BRIEF DESCRIPTION OF THE DRAWINGS

A general architecture that implements the various features of the embodiments will now be described with reference to the drawings. The drawings and the associated descriptions are provided to illustrate the embodiments and not to limit the scope of the invention.

FIG. 1 is an exemplary perspective view of a portable computer according to the first embodiment;

FIG. 2 is an exemplary perspective view of the portable computer according to the first embodiment, viewed from underneath;

FIG. 3 is an exemplary plan view of the portable computer according to the first embodiment, viewed from underneath;

FIG. 4 is an exemplary partially enlarged plan view of the portable computer according to the first embodiment;

FIG. 5 is an exemplary cross sectional view of the portable computer taken along the line F5-F5 of FIG. 4;

FIG. 6 is an exemplary perspective view of the cross section of the portable computer taken along the line F5-F5 of FIG. 4;

FIG. 7 is an exemplary perspective view of a battery lock of the first embodiment;

FIG. 8 is an exemplary plan view of the portable computer according to the second embodiment, viewed from underneath; and

FIG. 9 is an exemplary cross-sectional view of the portable computer taken along the line F9-F9 of FIG. 8.

### DETAILED DESCRIPTION

Various embodiments will be described hereinafter with reference to the accompanying drawings.

In general, according to one embodiment, an electronic apparatus includes a housing and a display unit. The housing includes a first end portion, a second end portion located on an opposite side to the first end portion and a hinge portion provided on the second end portion. The display unit is connected to the housing via the hinge portion. The housing further includes a lower cover, an upper cover, a recessed surface and a plurality of projecting portions. The lower cover includes a bottom surface facing a placement surface on which the housing is placed, and an inclined surface provided from the bottom surface over to the first end portion and separating further from the placement surface towards the first end portion. The upper cover covers the lower cover. The recessed surface is recessed from the inclined surface, and includes a hole and a plurality of recessing portions arranged in a lattice manner together with the hole. The projecting portions project from the recessed surface.

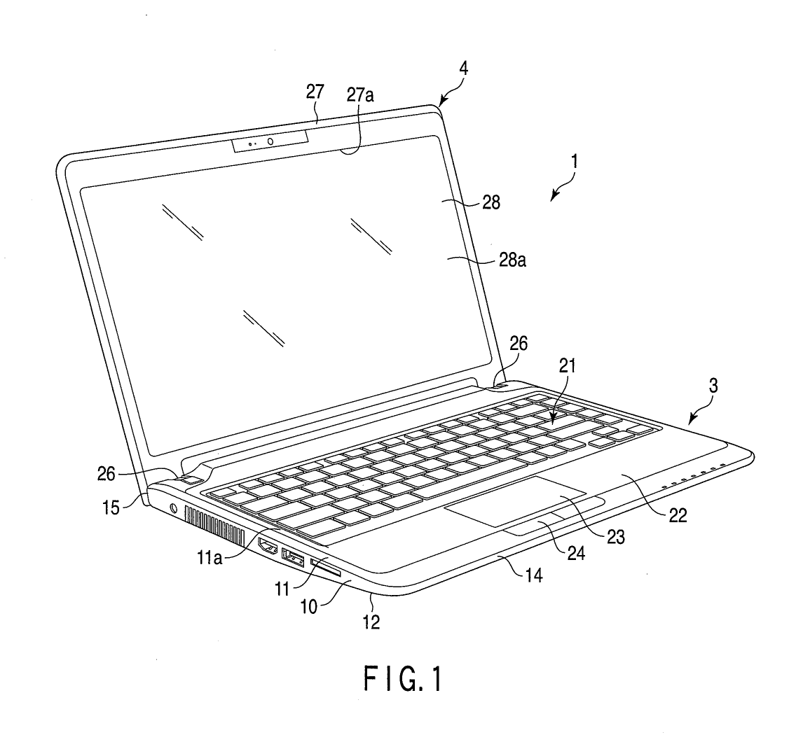

The first embodiment will now be described with reference to FIGS. 1 to 7. In this specification, the near side to the user (that is, user side) is defined as front, the far side from the user is rear, the left-hand side of the user is left, the right-hand side of the user is right, the upper side from the user's position is up and the lower side from the user's position is down.

FIG. 1 is a perspective view showing a portable computer 1. The portable computer 1 is an example of the electronic apparatus. As shown in FIG. 1, the portable computer 1 comprises a main unit 3 and a display unit 4.

The main unit 3 comprises a flat box-shaped housing 10. The housing 10 comprises an upper cover 11 and a lower cover 12. The lower cover 12 is an example of the bottom member. The upper cover 11 is mounted on the lower cover 12, and covers the lower cover 12. The upper cover 11 is formed of a synthetic resin. A lustrous metallic color sheet is adhered onto the surface of the upper cover 11.

Further, the housing 10 comprises a first end portion 14 and a second end portion 15. The first end portion 14 is an example of the peripheral portion of the housing. The first end portion 14 is a front end portion of the housing 10. The second end portion 15 is a rear end portion of the housing 10. The second end portion 15 is located on an opposite side to the first end portion 14.

A keyboard 21, a palm rest 22, a touch pad 23 and a pair of buttons 24 are provided on an outer surface 11a of the upper cover 11. The palm rest 22 is provided on the front side with respect to the keyboard 21. The touch pad 23 and buttons 24 are provided side by side around the center of the palm rest 22.

The display unit 4 is jointed to the rear end of the main unit 3 by means of a pair of hinge portions 26. The pair of hinge portions 26 are both provided in the second end portion 15 of the housing 10.

The display unit 4 is connected to the housing 10 via the hinge portions 26. The display unit 4 is made pivotable between a closed position and an open position around the hinge portions 26 as axis. In the closed position, the display unit 4 is lied on the main unit 3, whereas in the open position, the display unit 4 stands upright from the rear end of the main unit 3.

The display unit 4 comprises a flat box-shaped display housing 27 and a display module 28. The display module 28 is, for example, a liquid display, and it is housed in the display housing 27.

A display opening portion 27a is made in a front surface of the display housing 27. The display opening portion 27a exposes a screen 28a of the display module 28 to the outside of the display unit 4.

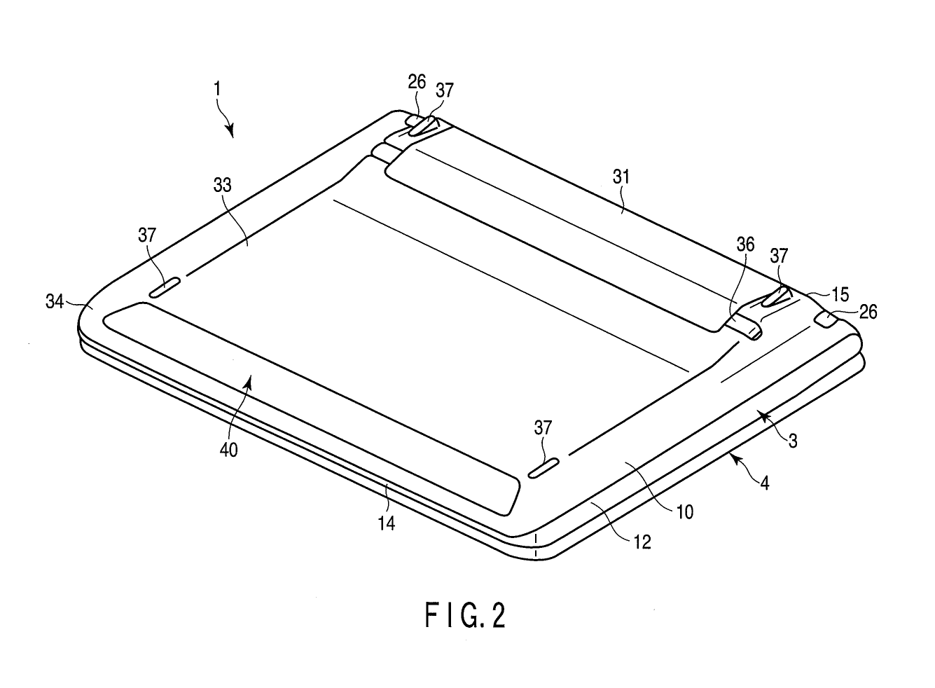

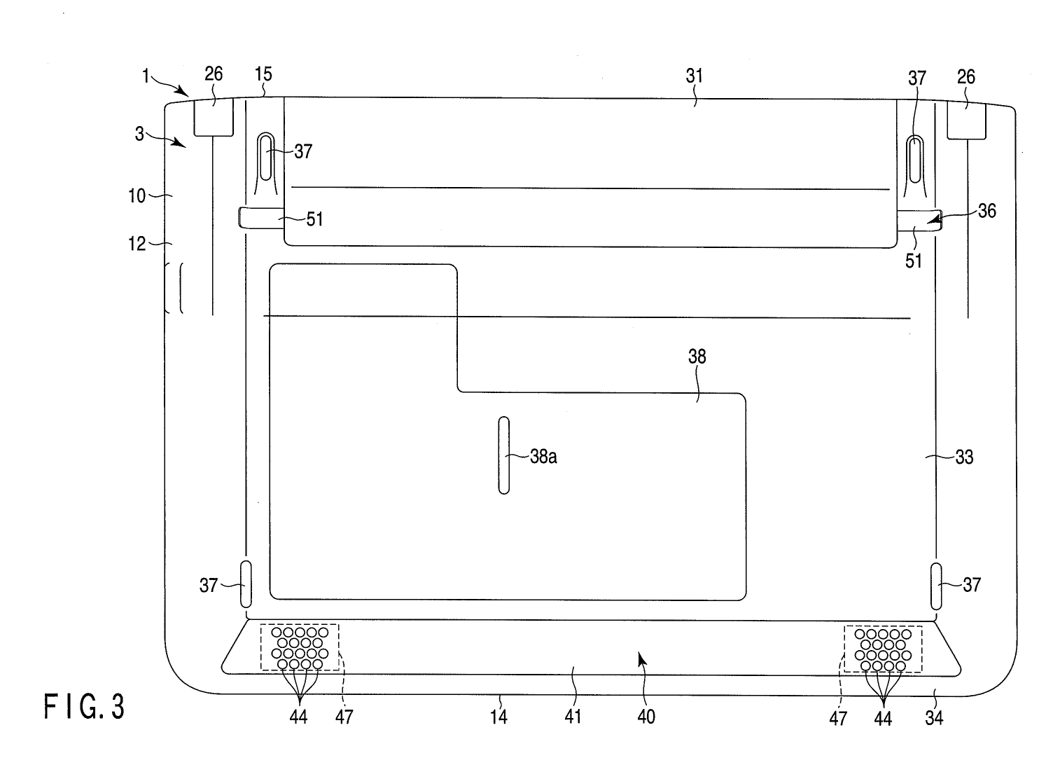

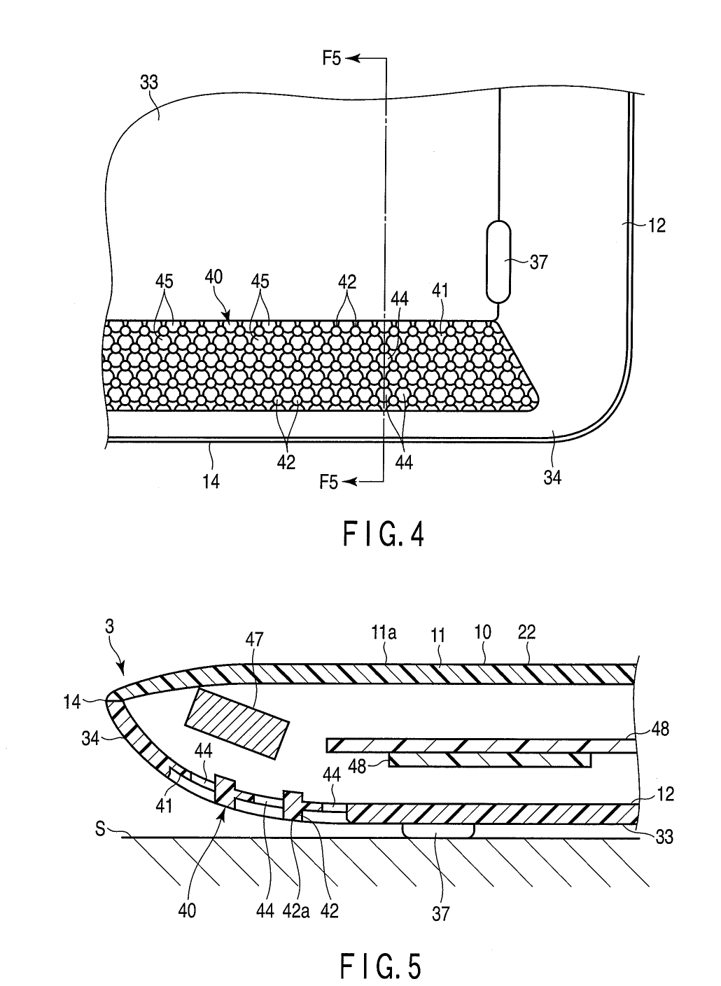

FIG. 2 is a perspective view of the portable computer 1 viewed from underneath, FIG. 3 is a plan view of the portable computer 1 viewed from underneath and FIG. 4 is a partially enlarged plan view of the portable computer 1. As shown in FIG. 2, a battery unit 31 is mounted on the second end portion 15 of the housing 10.

The lower cover 12 of the housing 10 comprises a bottom surface 33 and an inclined surface 34. When the potable computer 1 is placed on a placement surface S (shown in FIG. 5) of, for example, a desk, the bottom surface 33 faces the placement surface S.

As shown in FIG. 3, a battery lock 36, four rubber legs 37 and a storage cover 38 are provided on the bottom surface 33. The battery lock 36 fixates the battery unit 31 to the housing 10. The rubber legs 37 all support the housing 10.

The storage cover 38 covers the container portion provided in the housing 10. The container portion contains storages such as a hard disk drive and a memory. The storage cover 38 comprises a reinforcement portion 38a. The reinforcement portion 38a projects from the storage cover 38 towards the inside of the housing 10, and contacts the base of the container portion. When the storage cover 38 is pushed, the reinforcement portion 38a supports the storage cover 38.

FIG. 5 is a cross sectional view showing a part of the portable computer 1 taken along the line F5-F5 of FIG. 4. As shown in FIG. 5, the inclined surface 34 is provided from the bottom surface 33 over to the first end portion 14. The inclined surface 34 is formed such as to separate further away from the placement surface S as it approaches towards the first end portion 14.

As shown in FIG. 4, a processed portion 40 is provided on a portion of the inclined surface 34. The processed portion 40 is provided along the first end portion 14 and it is utilized as a member to prevent slipping. The processed portion 40 is formed as an integrated part to the housing 10.

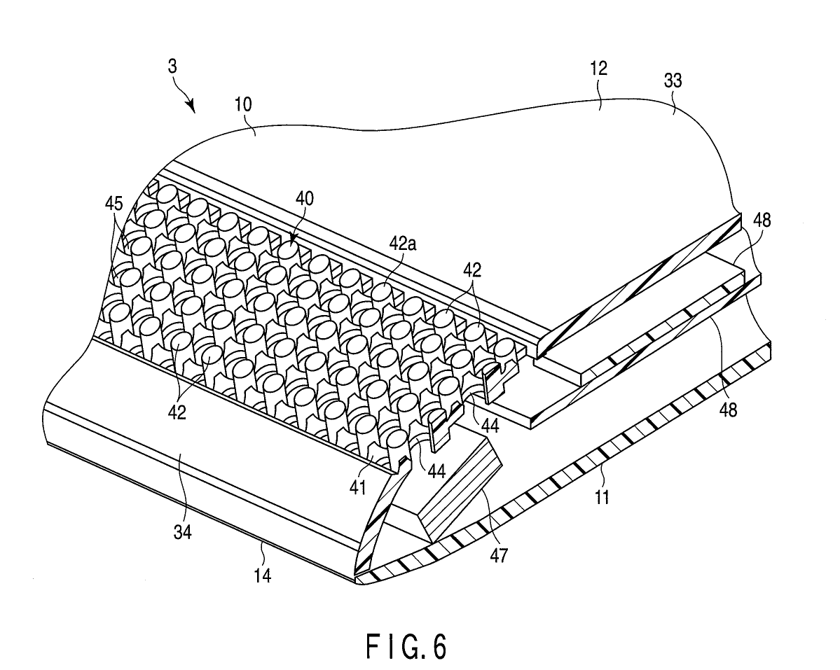

It should be noted that in FIGS. 2 and 3, the detailed illustration of the processed portion 40 is omitted. FIG. 6 is a perspective view of the cross section of a portion of the portable computer 1 taken along the line F5-F5 of FIG. 4. The details of the processed portion 40 are shown in FIGS. 4 to 6.

As shown in FIG. 4, the processed portion 40 comprises a recessed surface 41 and a plurality of projecting portions 42. The recessed surface 41 is provided as a recess in the inclined surface 34. In other words, the recessed surface 41 is provided such as to sink from the inclined surface 34.

A plurality of holes 44 and a plurality of recessing portions 45 are formed in the recess surface 41. The holes 44 each are a circular hole opened in the recessed surface 41. The holes 44 are formed from the processed portion 40 over to the inside of the housing 10. The holes 44 are arranged in a lattice manner.

The recessing portions 45 each recess further from the recessed surface 41. The recessing portions 45 each are a circular recess having the same diameter as that of the holes 44. That is, the recessing portions 45 have the same cross sectional shape as that of the holes 44. The recessing portions 45 are arranged such as to be mixedly with the holes 44 and they are arranged in a lattice matter together with the holes 44.

As shown in FIG. 5, the projecting portions 42 each project from the recessed surface 41 towards the outside of the housing 10. The projecting portions 42 are columnar projections independently projecting from the recessed surface 41. Each of the projecting portions 42 has a diameter smaller than that of the holes 44 or recessing portions 45. The distal ends 42a of the projecting portions 42 are located at slightly inner side of the housing 10 with respect to the inclined surface 34.

As shown in FIG. 4, the projecting portions 42 are arranged in a lattice manner. The arrangement of the projecting portions 42 is made to detour the recessing portions 45 and holes 44 which are arranged also in lattice manners.

As shown in FIG. 5, a pair of loudspeakers 47 and a plurality of circuit boards 48 are housed inside the housing 10. The circuit boards 48 each are a printed wiring board on which an electronic part such as CPU is mounted.

The loudspeakers 47 are electrically connected to the respective circuit boards 48. Each of the loudspeakers 47 is provided at a respective position corresponding to some of the holes 44. The speakers 47 output sound towards the outside of the housing 10 through these holes 44.

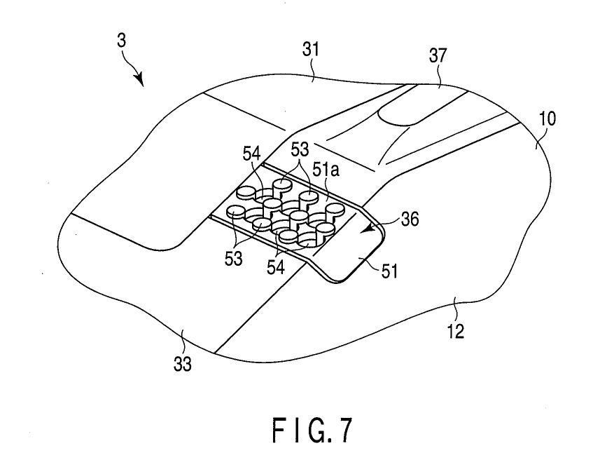

FIG. 7 is an enlarged perspective view of the battery lock 36. The battery lock 36 comprises a pair of latches 51. The latches 51 can slide to fixate the battery unit 31.

As shown in FIG. 7, a plurality of projections 53 and a plurality of recesses 54 are formed on a surface 51a of each of the latches 51. The projections 53 are columnar projections similar to the projecting portions 42, whereas the recesses 54 are circular recesses similar to the recessing portions 45. The projections 53 and the recesses 54 are utilized as a member to prevent slipping as they serve to cooperate with each other.

As described above, the portable computer 1 of this embodiment comprises such a configuration that the holes 44 are provided in the processed portion 40 so as to output sounds generated by the speakers 47. The processed portion 40 is utilized as a member to prevent slipping by means of the projecting portions 42 projecting from the recessed surface 41. With this configuration, the holes 44 are under cover of the projecting portions 42, and therefore the holes 44 are inconspicuous. Thus, the processed portion 40 can not only serve as a slippery prevention member, but also make the holes 44 inconspicuous.

The recessing portions 45 are arranged such as to be mixedly with the holes 44 and they are arranged in a lattice matter together with the holes 44. Therefore, the holes 44 are under cover of the recessing portions 45, and the holes 44 are inconspicuous. Further, the projecting portions 42 are arranged in a lattice manner, therefore the holes 44 are inconspicuous.

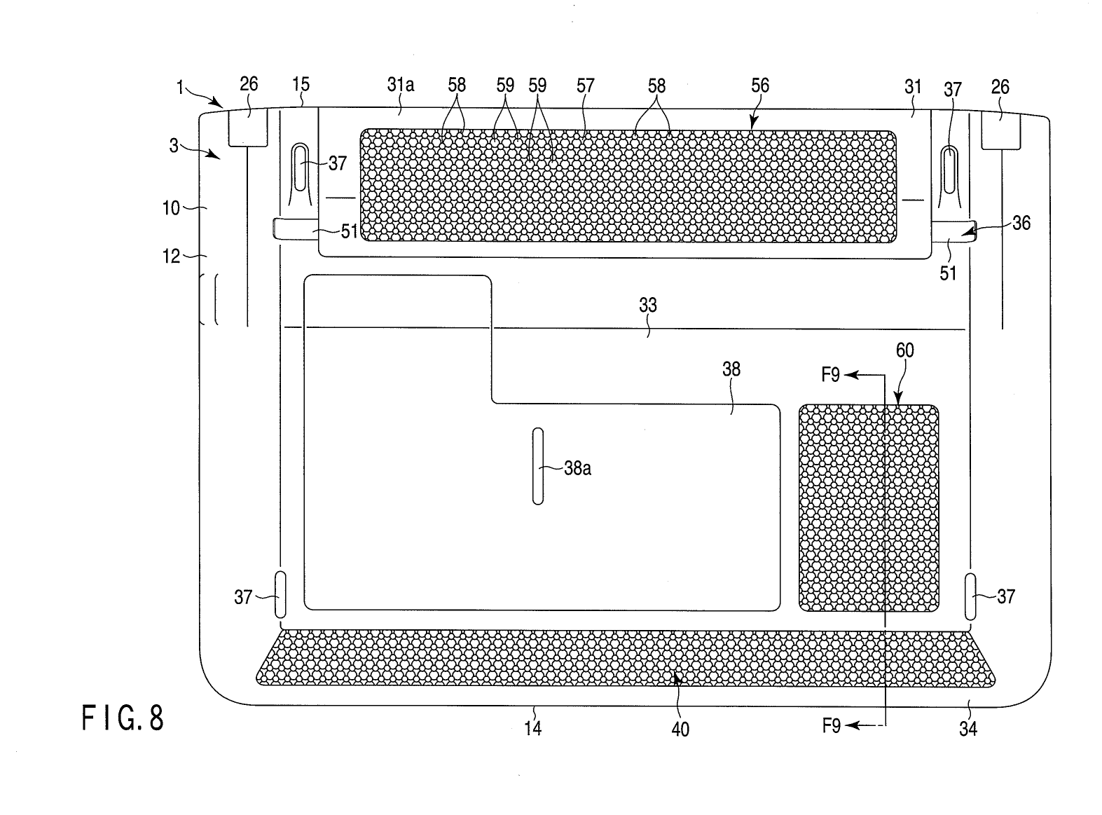

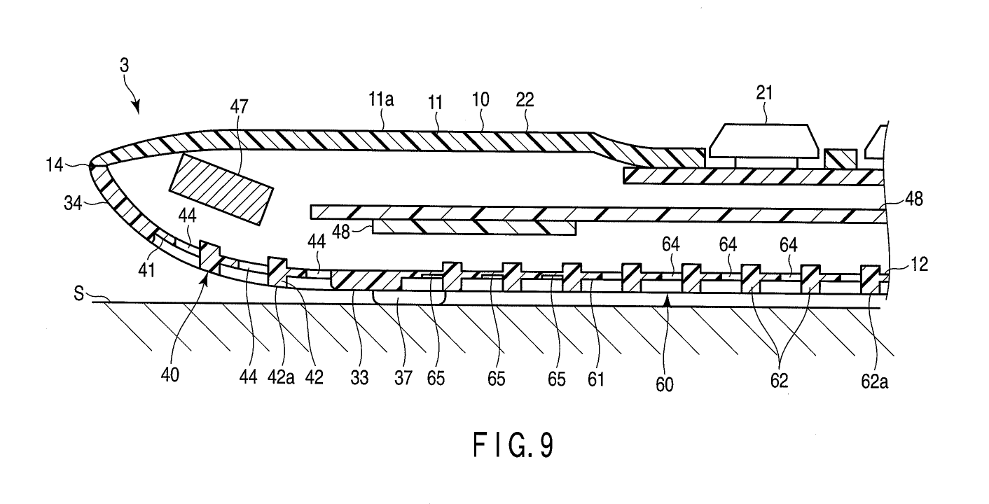

Next, the second embodiment will now be described with reference to FIGS. 8 and 9. In the following descriptions, the structural parts having the same functions as those of the portable computer 1 of the first embodiment will be denoted by the same reference numerals or symbols, and the explanations of these parts will not be repeated.

FIG. 8 is a plan view of a portable computer 1 according to the second embodiment, viewed from underneath. An anti-slippery portion 56 is provided on a surface 31a of a battery unit 31. The anti-slippery portion 56 comprises a depressed surface 57 and a plurality of projections 58. The depressed surface 57 is formed to be depressed from the surface 31a of the battery unit 31.

A plurality of recesses 59 are formed in the depressed surface 57. The recesses 59 each are a circular recess which further subsides from the depressed surface 57. The recesses 59 are arranged in a lattice manner.

The projections 58 are columnar projections independently projecting from the depressed surface 57. Each of the projections 58 has a diameter smaller than that of the recesses 59. The distal ends of the projections 58 are located at slightly inner side of the housing 10 with respect to the surface 31a.

As shown in FIG. 8, the anti-slippery portion 56 is formed into a shape similar to that of the processed portion 40. The anti-slippery portion 56 is different from the processed portion 40 in the respect that holes are not provided. In other words, the processed portion 40 is different from the anti-slippery portion 56 in the respect that holes 44 are provided.

A processed portion 60 is provided on a bottom surface 33 of a lower cover 12. The bottom surface 33 is an example of the outer surface exposed to the outside.

FIG. 9 is a cross-sectional view of the portable computer 1 taken along the line F9-F9 of FIG. 8. As shown in FIG. 9, the processed portion 60 comprises a recessed surface 61 and a plurality of projecting portions 62. The recessed surface 61 depresses from the bottom surface 33. In other words, the recessed surface 61 sinks from the bottom surface 33.

A plurality of air suction holes 64 and a plurality of recessing portions 65 are provided in the recessed surface 61. The air suction holes 64 are an example of the hole, and they are circular holes opening in the recessed surface 61. The suction holes 64 are provided from the processed portion 60 over to the inside of the housing 10. The air suction holes 64 are arranged in a lattice manner.

The recessing portions 65 each recess further from the recessed surface 61. The recessing portions 65 each are a circular recess having the same diameter as that of the air suction holes 64. In other words, the recessing portions 65 have the same cross sectional shape as that of the air suction holes 64. The recessing portions 65 are arranged such as to be mixedly with the air suction holes 64 and they are arranged in a lattice matter together with the air suction holes 64.

The projecting portions 62 each project from the recessed surface 61 towards the outside of the housing 10. The projecting portions 62 are columnar projections independently projecting from the recessed surface 61 and each having a diameter smaller than that of the air suction holes 64 or recessing portions 65. The distal ends 62a of the projecting portions 62 are located at slightly inner side of the housing 10 with respect to the bottom surface 33.

The projecting portions 62 are arranged in a lattice manner. The arrangement of the projecting portions 62 is made to detour the recessing portions 65 and the air suction holes 64 which are arranged also in lattice manners.

Air enters inside the housing 10 from the air suction holes 64. The air which flowed inside from the air suction holes 64 is made to flow outside the housing 10 from an air exhaust port by means of a fan provided inside the housing 10. As air flows through inside the housing 10, the electronic parts and heat sinks provided inside the housing 10 are cooled down.

In the portable computer 1 comprising the above-described structure, the air suction holes 64 through which air for cooling down flows in, are provided in the processed portion 60. With this configuration, the air suction holes 64 are made inconspicuous. Further, the processed portion 60 can serve as a slippery prevention member as the user carries the portable computer 1 in a hand.

As mentioned above, the holes made in the processed portion are provided not only as holes for passing sounding of the speaker or as air suction holes for cooling, but also in accordance with various usages. For example, the holes provided in the processed portion may be used as air exhaustion outlets or screw holes as well.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, the shape of the projecting portions provided in the processed portion is not limited to column, but also a pyramid or prism. Further, the shape of the holes and recessing portions made in the processed portion is not limited to circle, but various shapes can be applied.

Furthermore, the processed portion 40 is integrated with the housing 10, but the processed portion is not limited to this configuration. Alternatively, for example, a processed portion formed of a material having a high friction such as a synthetic rubber may be attached to the housing. Further, the location of the processed portion is not limited to a portion of the lower cover of the housing, but it may be provided on, for example, the display cabinet.

What is claimed is:

1. An electronic apparatus comprising:
a housing comprising a first end portion, a second end portion at an opposite side to the first end portion and a hinge on the second end portion;
a display connected to the housing via the hinge,
wherein the housing comprises:
a lower cover comprising a bottom surface facing a placement surface on which the housing is placed, and an inclining surface having a first slope proximal the first end portion and a second slope proximal the placement surface, the second slope smaller than the first slope;
an upper cover covering the lower cover;
a recessed surface of the inclining surface, comprising a hole and a plurality of recessing portions in a grid pattern together with the hole; and
a plurality of projecting portions projecting from the recessed surface.

2. The electronic apparatus of claim 1, wherein a cross sectional shape of each of the recessing portions and a cross sectional shape of the hole are substantially the same.

3. The electronic apparatus of claim 1, wherein distal ends of the projecting portions are located on an inner side of the housing with respect to the inclining surface.

4. The electronic apparatus of claim 1, further comprising a speaker in the housing,
wherein the hole is at a position corresponding to the speaker.

5. An electronic apparatus comprising:
a housing comprising an outer surface; and
a processed portion on a portion of the outer surface,
wherein the processed portion comprises a plurality of projecting portions projecting towards the outside of the housing, a hole through between the processed portion and an inside of the housing, and a plurality of recessing portions in a grid pattern together with the hole.

6. The electronic apparatus of claim 5, wherein
the processed portion comprises a recessed surface in the outer surface,
the plurality of projecting portions projecting from the recessed surface, and
the hole is in the recessed surface.

7. The electronic apparatus of claim 6, wherein a cross sectional shape of each of the recessing portions and a cross sectional shape of the hole are substantially the same.

8. The electronic apparatus of claim 6, wherein distal ends of the projecting portions are located on an inner side of the housing with respect to the outer surface.

9. The electronic apparatus of claim 5, wherein
the housing faces the placement surface on which the housing is placed, and comprises a bottom member which comprises the outer surface, and
the processed portion is provided along a peripheral portion of the housing.

10. The electronic apparatus of claim 9, further comprising a speaker in the housing,
wherein the outer surface comprises a inclining surface being away from the placement surface towards the peripheral portion of the housing,
the processed portion is in the inclining surface, and
the hole is at a position corresponding to the speaker.
